(19) United States
(12) Patent Application Publication
(10) Pub. No.: US 2022/0270394 A1
(43) Pub. Date: Aug. 25, 2022

(54) PACKAGE STRUCTURE OF FINGERPRINT RECOGNITION CHIP MODULE AND MANUFACTURING METHOD THEREOF

(71) Applicants: Yu-Sung Su, New Taipei City (TW); Shih Hua Wang, New Taipei City (TW)

(72) Inventors: Yu-Sung Su, New Taipei City (TW); Shih Hua Wang, New Taipei City (TW)

(21) Appl. No.: 17/678,152

(22) Filed: Feb. 23, 2022

(30) Foreign Application Priority Data
Feb. 24, 2021 (TW) 110106526

(51) Int. Cl. G06V 40/13

(52) U.S. Cl. CPC G06V 40/1329; G06V 40/1306

(57) ABSTRACT

A method for manufacturing a package structure of a fingerprint recognition chip module is provided and including: providing a carrier plate with a chip accommodation area; setting a fingerprint recognition chip having a recognition area in the chip accommodation areas; connecting the fingerprint recognition chip electrically to the circuit carrier; optionally applying a coating material on the chip accommodation area of the carrier plate, and optionally applying the coating material on the recognition area; and covering the chip accommodation area of the carrier plate with a covering layer except for the recognition area. The chip accommodation area is further configured to accommodate either an encapsulated or an unencapsulated security encryption chip, either an encapsulated or an unencapsulated micro processing chip, either an encapsulated or an unencapsulated power processing chip, and a plurality of resistors and a plurality of capacitors.

### CROSS-REFERENCE TO RELATED APPLICATION

This application claims priority of Taiwan patent application No. 110106526, filed on Feb. 24, 2021 the content of which are incorporated herein in its entirety by reference.

### BACKGROUND OF THE INVENTION

### 1. Field of the Invention

The present invention relates to a method for manufacturing a package structure of a chip module, and particularly to a method for manufacturing a package structure of a fingerprint recognition chip module.

### 2. The Prior Art

Existing fingerprint recognition devices, such as an optical fingerprint recognition device, occupy a relatively large volume because of the light source-assisted recognition function. Although a capacitive fingerprint recognition device has a light-weight and thin structure, the upper part of the capacitive fingerprint recognition device is arranged with a protective cover plate onto which users place their finger. The pocket in the outer surface of the protective cover plate, which arranged in the sensing block affects the appearance integrity of the electronic device.

In general, the fingerprint recognition chip packaging structure mainly includes a circuit carrier, a fingerprint recognition chip, a plurality of wires, and a packaging material. Most of the fingerprint sensing areas mentioned above are located on the surface of the fingerprint recognition chip. The thickness of the packaging material covering the fingerprint recognition chip will affect the sensitivity of the fingerprint recognition chip package structure.

The fingerprint recognition device can be improved by employing an improved package structure and manufacturing method thereof to reduce the volume and thickness of the package structure as well improve the sensitivity of the device.

### SUMMARY OF THE INVENTION

To efficiently solve the aforementioned problem, the present invention describes a package structure of a fingerprint recognition chip module and provides a method for manufacturing the package structure of a fingerprint recognition chip module. This package and process includes: providing a carrier plate with a chip accommodation area; setting a fingerprint recognition chip having a recognition area in the chip accommodation areas; connecting the fingerprint recognition chip electrically to the circuit carrier; optionally applying a coating material on the chip accommodation area of the carrier plate, and optionally applying a coating material on the recognition area (or applying a coating to both the chip accommodation area and the recognition area and optionally the entire area of the module, in one process); and covering the chip accommodation area of the carrier plate with a covering layer except for the recognition area. The chip accommodation area is further configured to accommodate either an encapsulated or an unencapsulated security encryption chip, either an encapsulated or an unencapsulated micro processing chip, either an encapsulated or an unencapsulated power processing chip, and a plurality of resistors and a plurality of capacitors.

According to an embodiment of the present invention, the carrier board is FR-4 rigid substrate, FPC flexible substrate, BT substrate, ABF substrate, MIS substrate, MPI soft board or LCP soft board.

According to an embodiment of the present invention, a thickness of the material being coated is less than 25 um and the material has a dielectric constant in the range of 2-8.

According to an embodiment of the present invention, the covering layer is a composite plastic frame or liquid glue and has a thickness of less than 80um.

According to an embodiment of the present invention, a fingerprint chip sensor material of the fingerprint recognition chip can be Si, glass, conductive film or PCB.

The present invention further provides a package structure of a fingerprint recognition chip module, which includes: a carrier plate, a fingerprint recognition chip, a coating material and a covering layer. The carrier plate has a chip accommodation area. The fingerprint recognition chip has a recognition area in the chip accommodation areas, and is electrically connected to the circuit carrier. The coating material is coated on the chip accommodation area of the carrier plate, and is coated on the recognition area. The covering layer covers the chip accommodation area of the carrier plate except for the recognition area. The chip accommodation area is further configured to accommodate an unencapsulated security encryption chip, an unencapsulated micro processing chip, an unencapsulated power processing chip, a plurality of resistors and a plurality of capacitors.

The packaging structure of the fingerprint recognition chip module manufactured by using the manufacturing method of the present invention can reduce the volume and thickness of the packaging structure and maintain the elements included in the packaging structure in consideration of appearance by means of covering the cover layer.

Alternate embodiments may include applying the coating material selectively over the recognition area or selectively over the chip area. An alternative embodiment may utilize more than one material within the coating material to accommodate the requirements of the recognition area and the requirements of the chip accommodation area. Alternate embodiments may include combining the coating material and the covering layer in one or more areas of the module.

### BRIEF DESCRIPTION OF THE DRAWINGS

FIG. 1 is a schematic diagram of a smart card using a packaging structure of a fingerprint recognition chip module according to an embodiment of the present invention;

FIG. 2 is a schematic diagram of the packaging structure of the fingerprint recognition chip module of the embodiment of FIG. 1;

FIGS. 3A to 3D are schematic diagrams of the manufacturing process of the package structure according to an embodiment of the present invention.

### DETAILED DESCRIPTION OF THE PREFERRED EMBODIMENT

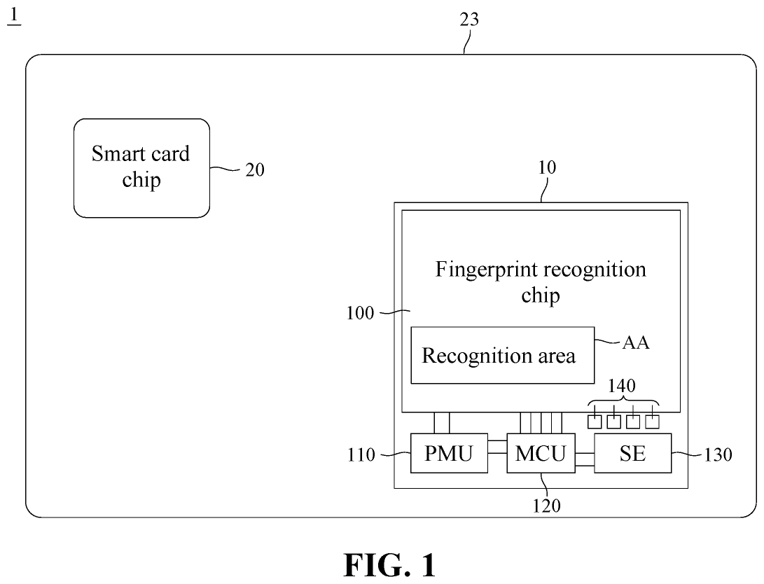

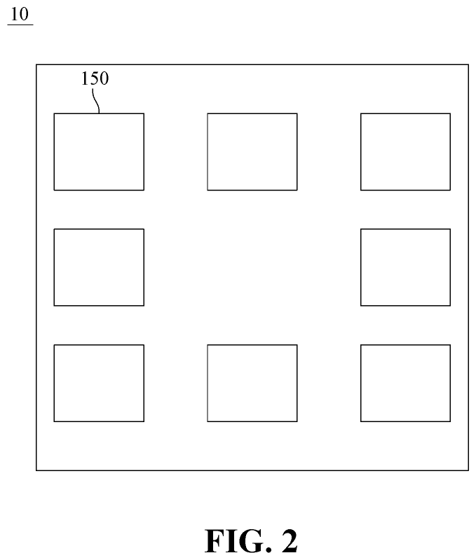

Please refer to FIG. 1 and FIG. 2, FIG. 1 is a schematic diagram of a smart card 1 using a packaging structure of a fingerprint recognition chip module according to an embodiment of the present invention, FIG. 2 is a schematic diagram of the packaging structure of the fingerprint recognition chip module 10 of the embodiment of FIG. 1. The smart card 1 includes a fingerprint recognition chip module 10 and a smart card chip 20. The fingerprint recognition chip module 10 and the smart card chip 20 may perform single/two-way communication through a serial peripheral interface (SPI) or inter-integrated circuit bus (VC) and other methods. The fingerprint recognition chip module 10 includes a fingerprint recognition chip 100, an unpackaged power management unit (PMU) 110, an unpackaged micro processing unit (MCU) 120, and an unpackaged security encryption (SE) chip 130, and resistance or capacitance element 140. The power processing chip 110, the microprocessor chip 120, and the resistor or capacitor 140 are coupled to the fingerprint recognition chip 100. The power processing chip 110 is coupled to the microprocessor chip 120 and is a power supply unit for controlling external power at 1.8V-5V, and used for internal components such as the microprocessor chip 120 and the security encryption chip 130. The security encryption chip 130 is coupled to the microprocessor chip 120, and the encryption format here can be AES or HMAC. The microprocessor chip 120 can be an ARM/RISC-V/8051 or other operable and encrypted micro processing unit. The back of the fingerprint recognition chip module 10 includes a plurality of metal contacts 150. The fingerprint recognition chip 100, the power processing chip 110, the microprocessor chip 120, the security encryption chip 130, and changeable number of the resistors or capacitors 140 can be adjusted or exchanged for the actual requirement (not limited to the financial field).

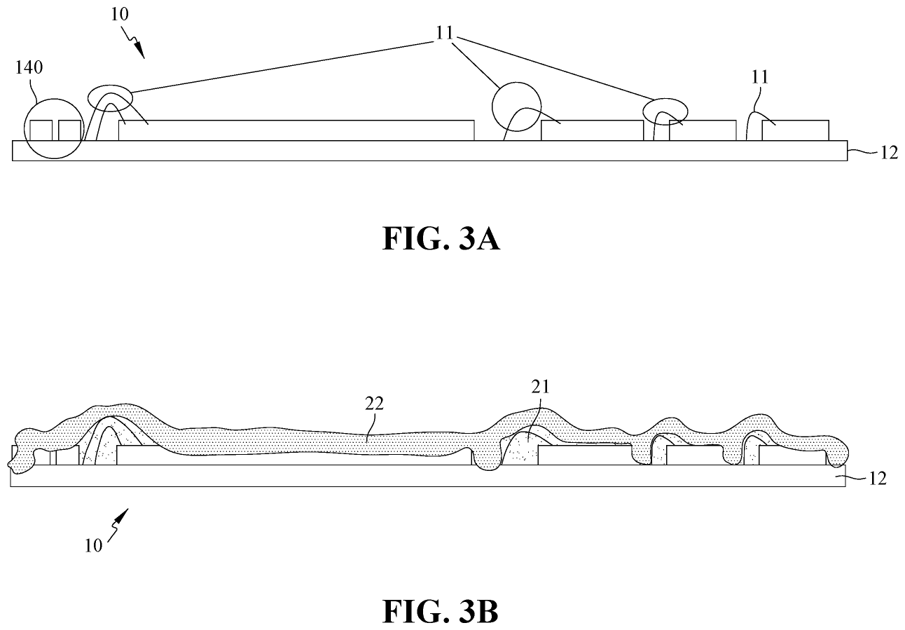

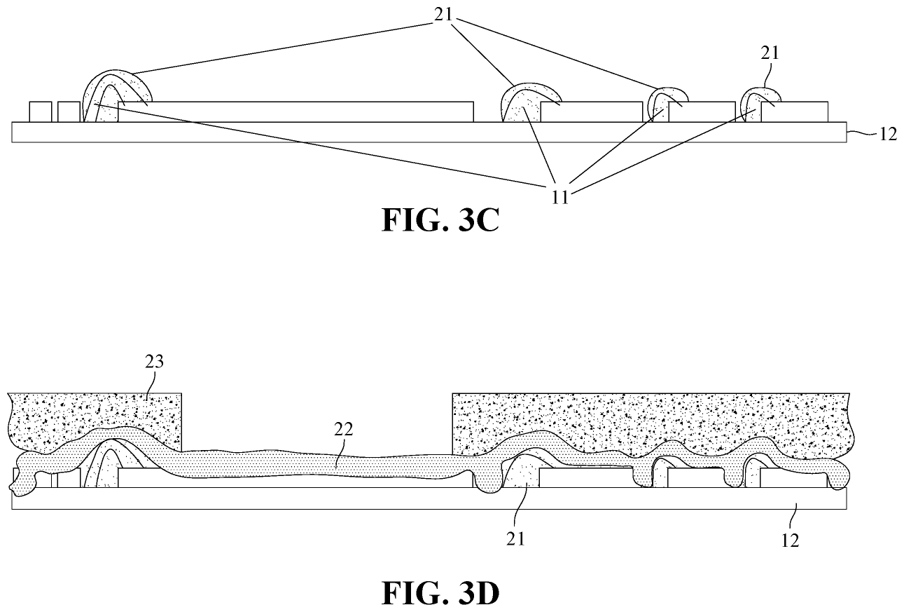

The package structure of the fingerprint recognition chip module 10 is manufactured according to the manufacturing order of FIGS. 3A to 3D. The manufacturing method of the package structure of the fingerprint recognition chip module of the present invention includes: providing a carrier plate 12 with a chip accommodation area, such as an FR-4 rigid substrate or an FPC flexible substrate; setting the fingerprint recognition chip 100 having a recognition area AA and being wire-bonded, the unpackaged power management unit 110, the unpackaged micro processing unit 120, and the unpackaged security encryption chip 130 in the chip accommodation areas, wherein passive components such as the resistor or capacitor 140 are fixed to the carrier plate 12 (composite materials such as BT/ABF) by surface mount tech (SMT). As shown in FIG. 3A, the fingerprint recognition chip module 10 includes a circuit carrier 12, and a chip on the chip accommodation area and the circuit carrier are connected by a bonding wire 11 to electrically connect the fingerprint recognition chip to the circuit carrier, and a bonding wire glue 21 is added to the bonding wire 11 as a protective layer for the bonding wire 11 (as shown in FIG. 3C); coating a coating material 22 on the chip accommodation area of the carrier plate 12, and coating the coating material 22 on the recognition area AA, as shown in FIG. 3B, the coating material 22 is added to the structure of the fingerprint recognition chip module 10 in FIG. 3A; and as shown in FIG. 3D, the covering layer 23 is covered by the covering layer 23 except for the recognition area AA and the smart card chip 20 hollowed out and exposed. The covering layer 23 is made of plastic or liquid colloid (or UV solid), which can fit and attach the material coating 22 through the protrusions of the bonding wire 11, and maintain a flat surface by heat-bonding method.

In the embodiment, the carrier board having the chip accommodation area can be not only FR-4 rigid substrate, FPC flexible substrate, but also BT substrate, ABF substrate, MIS substrate, MPI soft board or LCP soft board. The fingerprint chip sensor of the fingerprint recognition chip 100 can be made of Si, glass, conductive film, PCB and other materials, which is arranged in the chip accommodation area and electrically connected to the circuit carrier 12. The coating material 22 is coated on the chip accommodation area of the carrier plate 12, and the coating material 22 has a thickness of less than 25 um and a dielectric constant in the range of 2-8. The covering layer 23 here is a composite plastic frame or liquid glue and has a thickness of less than 80 um, covering the chip accommodation area of the carrier plate 12, and the covering layer 23 will not cover the recognition area AA after the coating material 22 covers the recognition area AA and the smart card chip 20. The fingerprint recognition chip 100 is arranged in the chip accommodation area together with the unpackaged security encryption chip 130, the microprocessor chip 120, the power processing chip 110, and the resistor or capacitor 140 as shown in FIG. 1.

The packaging structure of the fingerprint recognition chip module manufactured by using the manufacturing method of the present invention can reduce the volume and thickness of the packaging structure and maintain the elements included in the packaging structure in consideration of appearance by means of covering the cover layer.

The present invention is not limited to the above-mentioned embodiments, it is obvious to those skilled in the art that various modifications and changes can be made to the present invention without departing from the spirit or scope of the present invention.

Therefore, the present invention is intended to cover the modifications and changes made to the present invention or falling within the scope of the attached claims and its equivalent scope.

What is claimed is:

1. A method for manufacturing a package structure of a fingerprint recognition chip module, which comprises:
providing a carrier plate with a chip accommodation area;
setting a fingerprint recognition chip having a recognition area in the chip accommodation areas;
connecting the fingerprint recognition chip electrically to the circuit carrier;
optionally applying a coating material on the chip accommodation area of the carrier plate, and optionally applying the coating material on the recognition area; and
covering the chip accommodation area of the carrier plate with a covering layer except for the recognition area;
wherein the chip accommodation area is further configured to accommodate either an encapsulated or an unencapsulated security encryption chip, either an encapsulated or an unencapsulated micro processing chip, either an encapsulated or an unencapsulated power processing chip, and a plurality of resistors and a plurality of capacitors.

2. The method of claim 1, wherein the carrier board is FR-4 rigid substrate, FPC flexible substrate, BT substrate, ABF substrate, MIS substrate, MPI soft board or LCP soft board.

3. The method of claim 1, wherein a thickness of the material being coated is less than 25 um and the material has a dielectric constant in the range of 2-8.

4. The method of claim 1, wherein the covering layer is a composite plastic frame or liquid glue and has a thickness of less than 80 um.

5. The method of claim 1, wherein a fingerprint chip sensor material of the fingerprint recognition chip can be Si, glass, conductive film or PCB.

6. A package structure of a fingerprint recognition chip module, which comprises:
a carrier plate having a chip accommodation area;
a fingerprint recognition chip having a recognition area in the chip accommodation areas, and being electrically connected to the circuit carrier;
a coating material being coated on the chip accommodation area of the carrier plate, and being coated on the recognition area; and
a covering layer covering the chip accommodation area of the carrier plate except for the recognition area;
wherein the chip accommodation area is further configured to accommodate an unencapsulated security encryption chip, an unencapsulated micro processing chip, an unencapsulated power processing chip, a plurality of resistors and a plurality of capacitors.

7. The package structure of claim 6, wherein the carrier board is FR-4 rigid substrate, FPC flexible substrate, BT substrate, ABF substrate, MIS substrate, MPI soft board or LCP soft board.

8. The package structure of claim 6, wherein a thickness of the material being coated is less than 25 um and the material has a dielectric constant in the range of 2-8.

9. The package structure of claim 6, wherein the covering layer is a composite plastic frame or liquid glue and has a thickness of less than 80 um.

10. The package structure of claim 1, wherein a fingerprint chip sensor material of the fingerprint recognition chip can be Si, glass, conductive film or PCB.
